(19) United States
(12) Patent Application Publication
(10) Pub. No.: US 2022/0380896 A1
(43) Pub. Date: Dec. 1, 2022

(54) SEMICONDUCTOR PROCESS SURFACE MONITORING

(71) Applicant: Tokyo Electron Limited, Tokyo (JP)

(72) Inventors: Jianping Zhao, Austin, TX (US); John Carroll, Austin, TX (US); Peter Lowell George Ventzek, Austin, TX (US)

(21) Appl. No.: 17/332,581

(22) Filed: May 27, 2021

(51) Int. Cl. C23C 16/455; H01J 37/32

(52) U.S. Cl. CPC C23C 16/45536; H01J 37/32009; H01J 2237/0437

(57) ABSTRACT

An exemplary apparatus includes a chamber that includes a first window and a second window; a substrate holder configured to hold a substrate in the processing chamber; an infrared light (IR) source configured to generate a collimated IR beam; a first optical assembly configured to transmit the collimated IR beam into the chamber through the first window and direct the collimated IR beam at an incident angle of Brewster's angle with a front side of the substrate; and a second optical assembly configured to receive the collimated IR beam reflected at a back side of the substrate through the second window and direct the collimated IR beam to an optical sensor system.

### TECHNICAL FIELD

The present invention relates generally to process monitoring, and, in particular embodiments, to semiconductor process surface monitoring.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Process flows used to form the constituent structures of semiconductor devices often involve depositing and removing a variety of materials while a pattern of several materials may be exposed in a surface of the working substrate.

Advanced process control that involves in-situ process monitoring and fault detection in semiconductor manufacturing is essential for reproducible production of complex structures. As the minimum dimension of features in a patterned layer has shrunk periodically and new materials have been introduced in ICs, the need for improved process monitoring to assure process compliance and cost reduction has increased.

### SUMMARY

In accordance with an embodiment of the present invention, an apparatus includes a chamber that includes a first window and a second window; a substrate holder configured to hold a substrate in the processing chamber; an infrared light (IR) source configured to generate a collimated IR beam; a first optical assembly configured to transmit the collimated IR beam into the chamber through the first window and direct the collimated IR beam at an incident angle of Brewster's angle with a front side of the substrate; and a second optical assembly configured to receive the collimated IR beam reflected at a back side of the substrate through the second window and direct the collimated IR beam to an optical sensor system.

In accordance with an embodiment of the present invention, an apparatus includes a chamber; a substrate holder configured to hold a substrate; an infrared light (IR) source configured to generate an IR beam; a collimator to collimate the IR beam and generate a collimated IR beam; an IR detector configured to output electrical signals representing a spectral content of the IR beam; a microprocessor; and a memory having a program including instructions to: direct the collimated IR beam to a front side of the substrate at an incident angle of Brewster's angle; direct the collimated IR beam reflected from a reflective coating on a back side of the substrate to the IR detector; detect and record an absorption of the reflected IR beam at the IR detector; and obtain an IR absorption spectrum.

In accordance with an embodiment of the present invention, an apparatus includes a processing chamber; a vacuum pumping system; a gas injection system; a substrate holder configured to hold a substrate in the processing chamber; an infrared light (IR) source configured to generate an IR beam; a collimator to collimate the IR beam and generate a collimated IR beam; an IR detector configured to output electrical signals representing a spectral content of the IR beam; a microprocessor; and a memory having a program including instructions to: perform a process step in the processing chamber to process the substrate; direct the collimated IR beam to the substrate at an incident angle of Brewster's angle; direct a reflected IR beam from the substrate to the IR detector; detect and record an absorption of the reflected IR beam at the IR detector; and obtain a IR absorption spectrum of the substrate, where the IR source is configured to generate an IR beam and the IR detector is configured to detect the absorption during the process step.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1C schematically illustrates a design of an in-situ double-transmission Fourier-transform infrared spectroscopy (FTIR) in accordance with an embodiment of this disclosure, wherein FIG. 1A illustrates an example FTIR system, FIG. 1B illustrates a diagram of light path near and within a substrate in accordance with FIG. 1A, and FIG. 1C illustrates another example FTIR system in accordance with alternate embodiments;

FIGS. 2A and 2B illustrate example plasma processing tools comprising an in-situ double-transmission FTIR, wherein FIG. 2A illustrates a plasma processing tool in accordance with an embodiment, and FIG. 2B illustrates another plasma processing tool in accordance with an alternate embodiment;

FIG. 2C illustrates an example cluster tool comprising an in-situ double transmission FTIR in a metrology chamber in accordance with another embodiment;

FIGS. 3A-3D schematically illustrates cross-sectional views of example substrates that may be characterized by the double-transmission FTIR in accordance with various embodiments, wherein FIG. 3A illustrates an example substrate with a top thin film, FIG. 3B illustrates another example substrate with filled vertical recesses, FIG. 3C illustrates yet another example substrate with a layer with sidewalls, and FIG. 3D illustrates further alternate example substrate with multilayers on top;

FIG. 3E illustrates a diagram of light path near and within the substrate in accordance with FIG. 3A; and

FIG. 4 illustrates an example process flow of a cyclic layer-by-layer process comprising in-situ double-transmission FTIR measurements as a semiconductor process diagnostic tool in accordance with an embodiment.

### DETAILED DESCRIPTION OF ILLUSTRATIVE EMBODIMENTS

This application relates to a system of process monitoring during semiconductor device fabrication, more particularly to in-situ surface monitoring system based on double transmission Fourier-transform infrared spectroscopy (FTIR) integrated with a semiconductor processing tool. In typical semiconductor fabrication steps such as etching and film deposition processes, test substrates are characterized after the processing steps by various post-process analysis techniques (ex-situ). However, such a post-process analysis may tend to be time-consuming, inefficient, increasingly more expensive, and may cause wafer scrap. Therefore, an efficient real-time (in-situ) monitoring technique within a semiconductor processing tool may be desired. Embodiments of the present application disclose systems and methods of in-situ surface monitoring of a substrate in a processing chamber using double-transmission FTIR.

The systems and methods described in this disclosure may advantageously reduce the need for conventional ex-situ characterization for semiconductor device parameters and thereby improve the process efficiency through optimization of process parameters. In addition, the system of in-situ double transmission FTIR in accordance with embodiments of this disclosure may enable early recognition of a possible faulty process as well as prevent a catastrophic failure of the processing tool.

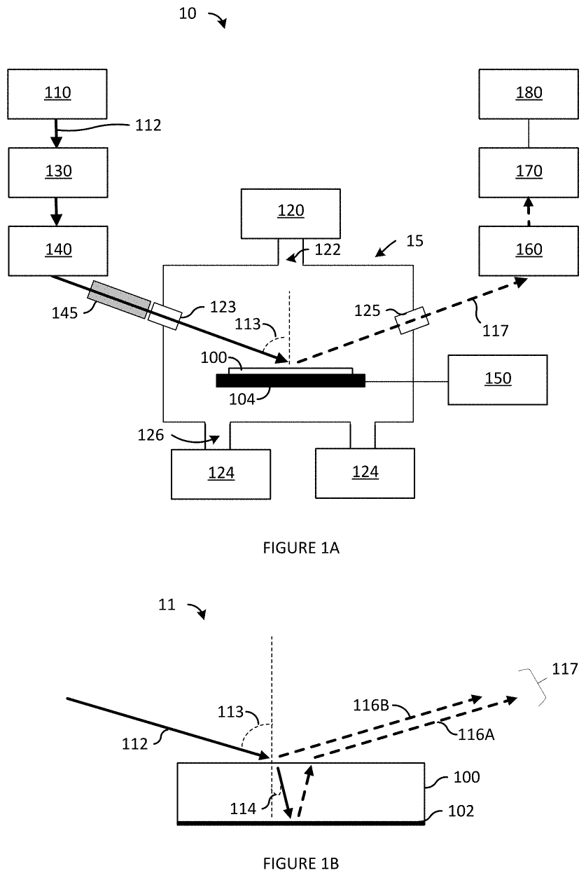

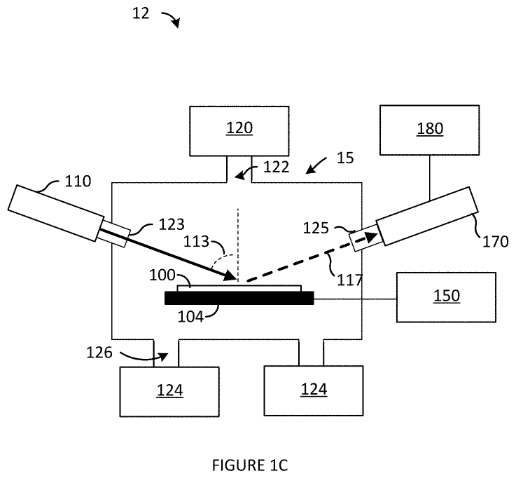

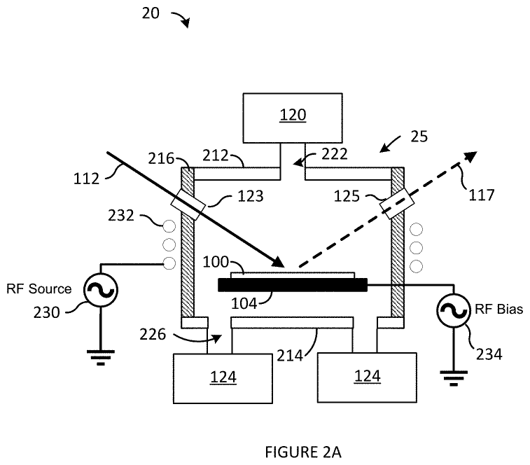

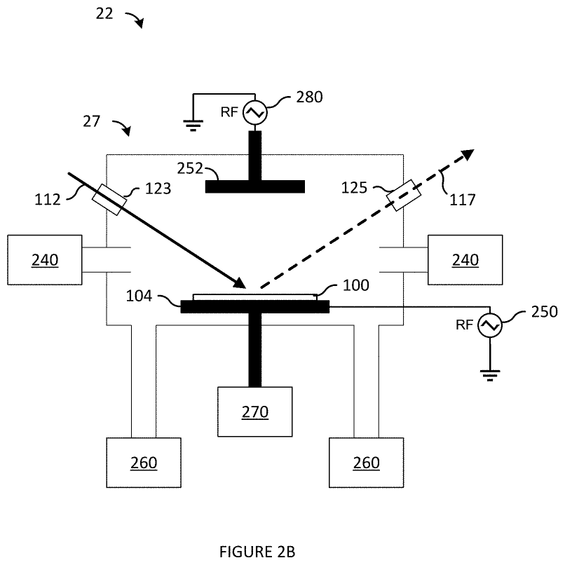

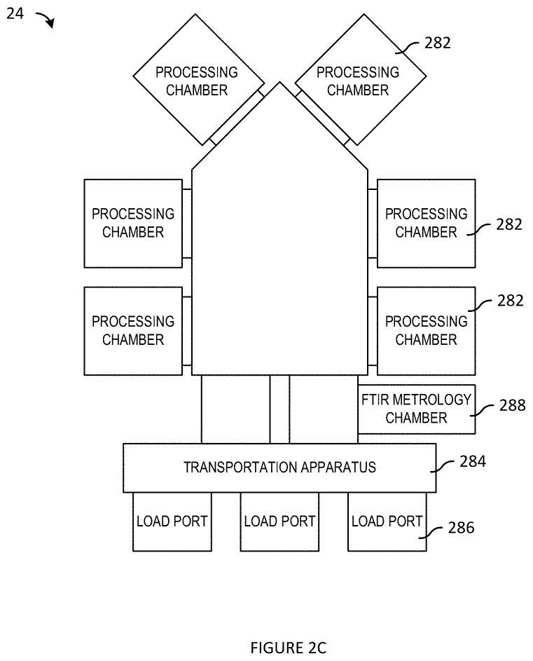

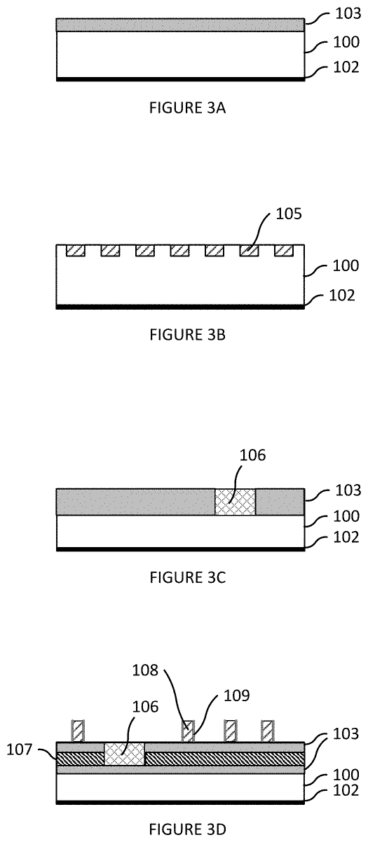

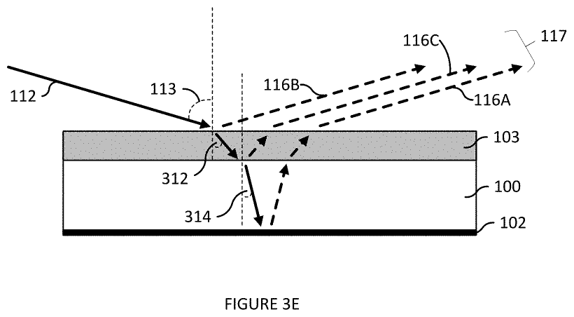

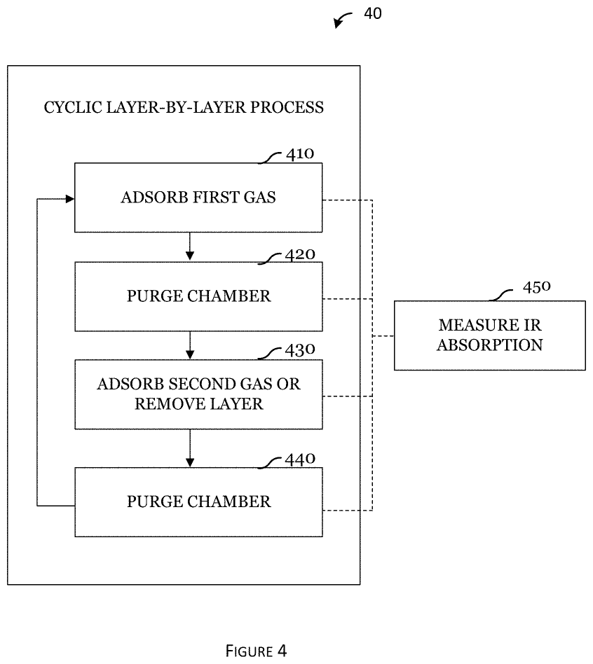

In the following, FIG. 1A illustrates an example FTIR system and FIG. 1B illustrates a diagram of light path near and within a substrate in accordance with FIG. 1A. In FIGS. 2A and 2B, example plasma processing tools comprising an in-situ double-transmission FTIR are illustrated in accordance with several embodiments. In FIGS. 3A-3D, example substrates that may be characterized by the double-transmission FTIR are schematically illustrated in accordance with various embodiments. FIG. 3E illustrates a diagram of light path near and within a substrate in accordance with FIG. 3A. FIG. 4 illustrates an example process flow of a cyclic layer-by-layer process comprising in-situ double-transmission FTIR measurements as a semiconductor process diagnostic tool in accordance with an embodiment.

FIG. 1A illustrates a cross-sectional view of an example processing system comprising in-situ double-transmission Fourier transform infrared spectroscopy (FTIR) in accordance with various embodiments.

In FIG. 1A, an in-situ double-transmission FTIR system 10 is integrated with a chamber 15. In various embodiments, the chamber 15 is a processing chamber, as illustrated in FIG. 1A, where a semiconductor fabrication step may be performed. In certain embodiments, as later described in FIGS. 2A and 2B, the chamber 15 may be a plasma processing chamber. In alternate embodiments, as later described in FIG. 2C, the chamber 15 is a metrology chamber of a cluster tool for semiconductor fabrication, connected to a processing chamber. In these embodiments, a substrate may be transported between the two chambers without being exposed to an outer environment. Further, in yet another embodiment, the chamber 15 may be a transfer chamber of a cluster tool, where FTIR measurements may be possible during substrate transfer between different chambers. In the embodiments where the chamber 15 is a processing chamber, a process gas or liquid may be introduced to the chamber 15 through a fluid inlet 122 and may be pumped out of the chamber 124 through a fluid outlet 126. The fluid inlet 122 and the fluid outlet 126 may comprise a set of multiple fluid inlets and fluid outlets, respectively. The fluid flow rates and chamber pressure may be controlled by fluid flow control systems 120 and 124 coupled to the fluid inlet 122 and the fluid outlet 126, respectively. The fluid flow control systems 120 and 124 may comprise various components such as high pressure gas canisters, valves (e.g., throttle valves), pressure sensors, gas flow sensors, liquid flow sensors, vacuum pumps, pipes, and electronically programmable controllers. In various embodiments, as described above, the chamber 15 may be a chamber different from a processing chamber (e.g., a metrology chamber and transfer chamber), and there may not be fluid inlets or outlets.

The chamber 15 further comprises a substrate holder 104 configured to hold a substrate 100. In certain embodiments, the substrate holder 104 may be further attached to a temperature controller 150 to heat and cool the substrate holder 104 to a process temperature and monitor the temperature of the substrate holder 104 and the substrate 100. Further, in some embodiments, the substrate holder 104 may have a capability of scanning the substrate 100 or may be equipped with a scanner so that double-transmission FTIR measurements may be performed at different regions of the substrate 100. The scanning capability may be advantageous especially in the in-situ double-transmission FTIR system 10 in a metrology chamber of a cluster tool because different orientations of a measuring spot in a patterned feature may also be measured in addition to different regions of the substrate 100.

In various embodiments, the measuring spot may have a diameter or a width between 5 mm and 50 mm, for example, in one embodiment, between 15 mm and 25 mm, although in other embodiments it may be smaller using for example an additional aperture.

In one or more embodiments, the substrate 100 may be a silicon wafer, or a silicon-on-insulator (SOI) wafer. In certain embodiments, the substrate may comprise a silicon germanium wafer, silicon carbide wafer, gallium arsenide wafer, gallium nitride wafer and other compound semiconductors. In other embodiments, the substrate comprises heterogeneous layers such as silicon germanium on silicon, gallium nitride on silicon, silicon carbon on silicon, as well layers of silicon on a silicon or SOI substrate. In one embodiment, the substrate 100 may be a high-resistivity (e.g., undoped) double side polished silicon wafer.

In various embodiments, the substrate 100 is a part of a semiconductor device, and may have undergone a number of steps of processing following, for example, a conventional semiconductor fabrication process flow. For example, the semiconductor structure may comprise a substrate 100 in which various device regions are formed. At this stage, the substrate 100 may include isolation regions such as shallow trench isolation (STI) regions as well as other regions formed therein. In other embodiments, the substrate 100 may include various 3D structures and layers useful for example in 3D-NAND, 3D-NOR, or dynamic random access memory (DRAM) device as well as 2-D/3-D transistors, which may be characterized by double-transmission FTIR enabled by the embodiments described in this disclosure. Some examples for structures of the substrate 100 are described in reference with FIGS. 3A-3D.

Further, an infrared light (IR) source 110 is configured to generate an IR beam 112. The IR source 110 may be an inert solid, for example, silicon carbide (SiC) in one embodiment, heated electrically to temperatures between 1500 K and 2000 K to generate IR in the mid-IR region (approximately 400 cm⁻¹ to 5000 cm⁻¹). In another embodiment, a plurality of quantum cascade lasers (QCL) may be used as a mid-IR source. For example, four QCLs may be used as the IR source 110, where the QCLs have a spectral tuning range from 1876.2 cm⁻¹ to 1675.0 cm⁻¹, 1736.1 cm⁻¹ to 1310.6 cm⁻¹, 1459.9 cm⁻¹ to 1175.1 cm⁻¹, and 1225.5 cm⁻¹ to 905.0 cm⁻¹, respectively. Continuous radiation approximating that of a black body results with a maximum radiant intensity between 5000 cm⁻¹ to 5900 cm⁻¹. For the near-IR (approximately 4000 cm⁻¹ to 10000 cm⁻¹), a tungsten-halogen lamp or other sources may be used. In certain embodiments, the IR source 110 comprises a plurality of lamps and/or heated elements to provide a sufficiently wide range of IR including the mid- and near-IR.

In certain embodiments, the IR source 110 may be a part of an interferometer. For example, the interferometer is a Michelson interferometer. Using the interferometer, an interferogram is obtained as raw data, which will be converted to a spectrum by Fourier transform.

In various embodiments, an optional polarizer 130 may be positioned after the IR source 110 as illustrated in FIG. 1A. The polarizer 130 filters a portion of the IR beam 112 according to a predetermined degree of polarization. The polarizer 130 may be adjusted to generate only p-polarized or s-polarized IR beam or varying degree of mixing p- and s-polarized IR beam. Alternately, the polarizer 130 may generate an IR beam having a range of polarization. In some embodiments, the IR beam 112 may be non-polarized IR beam without using the polarizer 130. In other embodiments, the polarizer 130 may be positioned in the path of a reflected IR beam 117 after the substrate 100. In another embodiment, a plurality of polarizers may be used with one polarizer positioned in the path of the IR beam 112 before the substrate 100 and another polarizer positioned in the path of the reflected IR beam 117. The use of a polarized light as the IR beam 112 may enhance a signal-to-noise ratio and also provide information of the orientations of molecules on the surface. Further, using differently polarized IR beam, the polarized light may enable selective detection of IR absorption by the surface species to molecules in the vapor phase. In certain embodiments, using a mixture of p- and s-polarized IR beam and varying a degree of the mixing, information on thickness and heterogeneity of thin layers over the substrate 100 may be characterized. The polarizer 130 may be a wire grid polarizer, for example, made of zinc selenide (ZnSe).

The direction of the IR beam 112 may be precisely adjusted by a first optical assembly 140. In various embodiments, the IR beam 112 may be directed to the substrate in the chamber at an incident angle of Brewster's angle 113. The incident angle of Brewster's angle 113 refers to any angle of incidence that is essentially around the Brewster's angle respect to the normal to the surface of the substrate 100. The first optical assembly 140 may compose a plurality of flat mirrors and/or waveguides. In one embodiment, the IR source 110 may be a MEMS-based IR interferometer chip package directly mounted on the first transmissive window 123. In such an embodiment, the first optical assembly 140 may be omitted.

As illustrated in FIG. 1A, a collimator 145 may be used to collimate the IR beam 112 in accordance with various embodiments. The collimator 145 may be a separate component as illustrated. In certain embodiments, the collimator 145 may be integrated as a part of the first optical assembly 140 or a part of the IR source 110. In some embodiments, the IR source 110 may generate a collimated IR beam and no further collimation may not be performed. Collimating allows the IR beam 112 to have parallel rays of light and may advantageously enable precise control of incident angle relative to other beams such as a focused beam. The use of the collimated IR beam may also allow various FTIR system configurations with physical flexibility that can be beneficial for integrating the FTIR system with a processing chamber system. The collimator 145 may comprise a waveguide in one embodiment and an optical lens in another embodiment. For example, the waveguide for the collimator 145 may comprise a solid-core fiber, a hollow core glass waveguide, or a micro-structured fiber (so-called photonic crystal fiber). The use of a fiber waveguide may advantageously offer flexibility and compactness of the collimator 145 compared with conventional collimators such as an optical lens and a parabolic mirror. When an optical lens is used as the collimator 145, an absorption of the IR beam 112 by the lens may be an issue. In the in-situ double-transmission FTIR system 10, it may also be difficult to achieve the incident angle of Brewster's angle using an optical lens or a parabolic mirror. The use of a waveguide as the collimator 145 may provide a better room for adjusting the configuration of the in-situ double-transmission FTIR system 10. Further, the use of a hollow waveguide fiber may have advantages of high power threshold, low insertion loss, low nonlinearity, and no end-reflection. In one embodiment, the inner part of a hollow waveguide fiber may comprise a silica capillary tube for an outer part and a metallic silver (Ag) layer coated by a single dielectric film of silver iodide (AgI), polystyrene (Ps), or by AgI/Ps double dielectric film for an inner part.

In certain embodiments, an optional iris diaphragm may be used to limit the beam size of the IR beam 112. The IR beam 112 with a smaller measuring spot size improves FTIR spatial resolutions.

Next, the IR beam 112 enters the chamber through the first transmissive window 123. The first transmissive window 123 may comprise a material transparent to infrared light (IR) such as potassium bromide (KBr), IR quartz, silicon (Si), and aluminum oxide.

FIG. 1B illustrates a diagram of light path for the IR beam 112 near and within the substrate 100 in accordance with FIG. 1A. As mentioned above, the IR beam may be directed by the first optical assembly 140 to have the incident angle of Brewster's angle 113, as illustrated in FIGS. 1A and 1B. In this disclosure, the incident angle of Brewster's angle refers to the Brewster's angle or an incident angle approximately around the Brewster's angle.

Exactly at the Brewster's angle, a p-polarized portion of the IR beam 112 is entirely transmitted through the front surface of the substrate 100 into the bulk of the substrate (refracted IR beam) with a refraction angle 114. On the other hand, an s-polarized portion of the IR beam 112 is entirely reflected at the front surface of the substrate 100 (a front-reflected IR beam 116B). Other portions of the IR beam 112 with different degrees of polarization may partially be reflected at the front surface of the substrate 100 (the front-reflected IR beam 116B) as well as transmitted into the bulk of the substrate 100 (refracted IR beam). The Brewster's angle θ_{B} depends on the refractive indices of two media (e.g., n₁ and n₂) that the light is transmitted through, and is defined as arctan (n₂/n₁) (i.e., tan θ_{B}=n₂/n₁). In various embodiments of this disclosure, a first medium may be air or vacuum and a second medium may be silicon. The embodiment system for in-situ double-transmission FTIR is based on the configuration where the incident light (e.g., the IR beam 112) is adjusted to have an incident angle (e.g., the incident angle of Brewster's angle 113) around a Brewster's angle.

In certain embodiments, where the substrate 100 includes various 3D structures and layers, there may be more than two media in the light path of the IR beam 112. In some of these embodiments, the Brewster's angle in this disclosure is selected based on the two major media: air or vacuum and a bulk material of the substrate. In one embodiment, as described in FIG. 3A for example, a thin film layer comprising silicon oxide may be formed over a silicon wafer substrate, and the Brewster's angle is selected for air or vacuum and silicon, rather than silicon oxide.

In certain embodiments, the incident angle of Brewster's angle 113 may be between 60° and 80° and adjustable for different measurements.

For example, the first medium is vacuum (n₁=1) and the second medium is silicon having a refractive index of about 3.4 (n₂=3.4), where the Brewster's angle is calculated about 73.6°. The relationship between the incident angle of Brewster's angle 113 (θ₁) and the refracted angle 114 (θ₂) is given by the Snell's law (n₁×sin θ₁=n₂×sin θ₂). In this example, when θ₁=73.6°, θ₂=14.0°. In one embodiment, the incident angle of Brewster's angle 113 may be 73.6°. In another embodiment, the incident angle of Brewster's angle 113 may be between 70° and 75°. In yet another embodiment, the incident angle of Brewster's angle 113 may be changed between FTIR measurements. For example, a set of FTIR measurements may be performed at 70°, 73°, and 75°. At these different incident angles of Brewster's angle 113, the ratio of reflection at the front surface and refraction may be different, advantageously providing information on thickness and heterogeneity of thin layers over the substrate 100 that may be present in certain embodiments. In different embodiments, the incident angle of Brewster's angle 113 may be scanned during a FTIR measurement.

As illustrated in FIG. 1B, at the front surface of the substrate 100, the IR beam 112 may be split into two paths. First, the front-reflected IR beam 116B, as described above, is a portion of the IR beam 112 that is reflected at the front surface of the substrate 100. Second, a portion of the IR beam 112 that is refracted and transmitted into the bulk of the substrate (refracted IR beam) may be reflected back at the back surface of the substrate 100. This portion of the IR beam from the back surface of the substrate 100 may exit the substrate 100 through the front surface (a back-reflected IR beam 116A). In the following, a sum of IR beams comprising the back-reflected IR beam 116A and front-reflected IR beam 116B. is collectively referred to as the reflected IR beam 117. Although not specifically described, the reflected IR beam 117 may also comprise any IR beam that may be reflected and/or refracted multiple times before exiting the substrate 100.

In certain embodiments, with a precise control of the incident angle of Brewster's angle 113 and polarization of the IR beam 112, the front-reflected IR beam 116B may be eliminated or minimized in the reflected IR beam 117. For example, if the IR beam 112 contains only the perfectly p-polarized light and is directed to the substrate 100 exactly at the Brewster's angle, there may be not reflection at the front surface of the substrate (i.e., no front-reflected IR beam 116B). By slightly shifting the incident angle and/or using a range of polarized light, the reflected IR beam 117 may contain both back-reflected IR beam 116A and front-reflected IR beam 116B.

The light path for the back-reflected IR beam 116A (112 to 116A) transmits the substrate 100 twice, thereby referring to the technique of FTIR described in this disclosure as double-transmission FTIR.

As illustrated in FIG. 1B, the substrate 100 may optionally comprise a back-side reflective coating 102 in certain embodiments. The back-side reflective coating 102 may prevent the IR beam 112 from further transmitting through the back surface of the substrate 100, and allow a total reflection of the IR beam 112 at the interface between the back surface of the substrate 100 and the back-side reflective coating 102. The back-side reflective coating 102 may comprise a metal, for example, aluminum, titanium, tantalum, tungsten, nitrides, for example, titanium nitride, tantalum nitride, tungsten nitride, silicides, for example, cobalt silicide, nickel silicide, and others. A metallic back-surface reflective coating may be applied by appropriate deposition techniques such as vapor deposition including chemical vapor deposition (CVD), physical vapor deposition (PVD), atomic layer deposition (ALD), as well as other plasma processes such as plasma enhanced CVD (PECVD) and other processes. Having the back-side reflective coating 102 may advantageously eliminate any interference or infringe patterns that might otherwise occur due to any possible air gap between the substrate 100 and the substrate holder 104. In various embodiments, the back-side reflective coating 102 may advantageously have a rough surface, thereby not necessarily requiring a smoothing step to make a mirror smooth surface. Further, in some embodiments, the substrate 100 may have a metallic coating already fabricated on the back surface for the purpose of bowing and stress control during preceding process steps. Such a metallic coating may serve as the back-side reflective coating during the double-transmission FTIR measurements, thereby not requiring a separate coating step to form the back-side reflective coating 102.

In some embodiments, the substrate 100 may not have the back-side reflective coating 102. In one embodiment, the back surface of the substrate 100 may be mirror polished to enhance the IR reflection at the back surface of the substrate 100.

Referring again to FIG. 1A, the reflected IR beam 117 exits the chamber 15 through a second transmissive window 125. The second transmissive window 125 may be the same material as the first transmissive window 123.

The direction of the reflected IR beam 117 may be precisely adjusted by a second optical assembly 160. In various embodiments, the reflected IR beam 117 may be directed to an optical sensor system 170. In one embodiment, the second optical assembly 160 may comprise a flat mirror and a parabolic mirror. An incident beam (e.g., the IR beam 112) that is a collimated parallel beam will be reflected off from the substrate 100 as a parallel beam, and therefore a parabolic mirror may be used to focus the parallel beam to a focal point where the detector is located. In another embodiment, the second optical assembly may comprise a set of flat mirrors. In yet another embodiment, the optical sensor system 170 may be an IR sensor package directly mounted on the second transmissive window 125 and the second optical assembly 160 may be omitted. In yet another embodiment, the first optical assembly 140 may be integrated with the IR source 110 and mounted on the first transmissive window 123. Similarly, the second optical assembly 160 may be integrated with the optical sensor system 170 and mounted directly on the second transmissive window 125. In accordance with such an embodiment, an example in-situ FTIR double-transmission system 12 is illustrated in FIG. 1C.

The optical sensor system 170 may be an IR detector and a part of a Fourier-transform Infrared (FTIR) spectrometer. The optical sensor system 170 may be configured to output electrical signals representing a spectral content of the reflected IR beam 117.

The electrical signals representing the spectral content of the reflected IR beam 117 may then be provided to a microprocessor 180 having a program to process the received electrical signals. In various embodiments, an algorithm based on Fourier transform may be used to convert an interferogram obtained as raw data into an IR absorption spectrum. IR absorption may occur when a molecule undergo a net change in its dipole moment as a consequence of its vibrational or rotational motion. The IR absorption spectrum therefore contains information of the abundance of various chemical species corresponding to their characteristic dipole moment transitions.

The double-transmission FTIR in accordance with embodiments of this disclosure allows relatively simple system designs without compromising sensitivity, and may be advantageous for the in-situ measurements in a semiconductor processing chamber over other FTIR techniques such as transmission FTIR or attenuated total reflection (ATR) FTIR that may require an advanced setup for wafer tilting or a special IR crystal, respectively.

In-situ double-transmission FTIR measurements enabled by the embodiments in this disclosure may not require a transfer of the substrate from one chamber to another, which may allow faster diagnostics of a semiconductor fabrication. Further, with an optional back-side reflective coating, no external attachment such as a mirror is needed. This feature may eliminate an issue of any contamination from the external attachment within the processing chamber, thereby enabling FTIR measurements without substantially changing an environment (e.g., gas composition) in the processing chamber.

Additionally, the embodiment system for double-transmission FTIR may be configured to measure a substrate of any size and maintain a conventional wafer arrangement commonly applied in a semiconductor fabrication process. Without complex system requirement, the double-transmission FTIR may be applicable to various semiconductor process systems, enabling in-situ surface monitoring of semiconductor fabrication process steps. Such semiconductor fabrication processes include various deposition processes such as chemical vapor deposition (CVD), physical vapor deposition (PVD), atomic layer deposition (ALD), as well as other plasma processes such as plasma enhanced CVD (PECVD). Similarly, the embodiment system may be applied to various etch processes such as wet etching, remote radical etching, non-plasma dry etching, reactive ion etch (RIE) process, and atomic layer etch (ALE). Further, the embodiment system may be applied to coating processes such as spin on coating for patterning photoresist, carbon hardmask materials and the like, and bottom-up polymer patterning for self-aligned monolayer (SAM) in gas or liquid phase. Other processes available for the embodiment system include thermal processes such as rapid thermal annealing (RTA), furnace diffusion, oxidation, and implantation for doping.

For example, the chamber 15 illustrated in FIG. 1A may be used for thermal deposition or etch processes such as thermal atomic layer deposition (ALD) and thermal atomic layer etch (ALE). Further, as described below, the double-transmission FTIR may also be integrated in a plasma system.

In FIGS. 2A and 2B, example plasma processing tools comprising an in-situ double-transmission FTIR are illustrated in accordance with several embodiments. In various embodiments, the in-situ double-transmission FTIR system may be integrated in a plasma system. In various embodiments, the plasma system may be configured to generate and sustain inductively coupled plasma (ICP), capacitively coupled plasma (CCP), microwave plasma (MW), or helical resonator plasma.

In FIG. 2A, an in-situ double-transmission FTIR system 20 is integrated with a plasma processing chamber 25 in accordance with an embodiment. Various elements including gas delivery and vacuum systems may be the same as an embodiment illustrated above in FIG. 1A and hence will not be described again. The plasma processing chamber 25 may be configured to sustain an inductively coupled plasma (ICP) directly above the substrate 100 loaded onto the substrate holder 104. An RF bias power source 234 and an RF source power source 230 may be coupled to respective electrodes of the plasma processing chamber 25. The substrate holder 104 may also be the electrode coupled to the RF bias power source 234. The RF source power source 230 is shown coupled to a helical electrode 232 coiled around a dielectric sidewall 216. In FIG. 2A, a gas inlet 222 is an opening in a top plate 212 and a gas outlet 226 is an opening in a bottom plate 214. The top plate 212 and bottom plate 214 may be conductive and electrically connected to the system ground (a reference potential). Various elements for generating, polarizing, directing, detecting, and analyzing the IR beam 112 and the reflected IR beam 117 may be the same as illustrated above in FIG. 1A and hence will not be described again.

In FIG. 2B, in accordance with another embodiment, an in-situ double-transmission FTIR system 22 is integrated with a plasma processing chamber 27. The example plasma processing chamber 27 may be configured to sustain capacitively coupled plasma (CCP), connected to a gas delivery system 240 on the side wall of the plasma processing chamber and a vacuum pump system 260. Gases may be introduced into the plasma processing chamber 27 through the gas delivery system 240. The substrate 100 may be mounted on the substrate holder 104 inside the plasma processing chamber 27. The substrate holder 104 may be a circular electrostatic chuck. The substrate 100 may be maintained at a desired process temperature using a temperature controller 270. Further, the substrate holder 104, as illustrated, may be connected to a first RF power source 250 and may be a bottom electrode, while a top electrode 252 is connected to a second RF power source 280 to power a plasma inside the plasma processing chamber 27. In various embodiments, the top electrode 252 may be a conductive coil located, over a top ceramic window, outside the plasma processing chamber 27. Various elements for generating, polarizing, directing, detecting, and analyzing the IR beam 112 and the reflected IR beam 117 may be the same as illustrated above in FIG. 1A and hence will not be described again.

The plasma systems shown in FIGS. 2A and 2B are by example only. In various alternative embodiments, the plasma system may be configured to sustain inductively coupled plasma (ICP) with RF source power coupled to a planar coil over a top dielectric cover. Pulsed RF power sources and pulsed DC power sources may also be used in some embodiments (as opposed to continuous wave RF power sources). Further, microwave plasma (MW) or other suitable systems may be used. In some embodiments, the plasma processing system 400 may be a resonator such as a helical resonator.

In addition, embodiments of the present invention may be also applied to remote plasma systems as well as batch systems. For example, the substrate holder may be able to support a plurality of substrates that are spun around a central axis as they pass through different plasma zones.

FIG. 2C illustrates an example cluster tool comprising an in-situ double transmission FTIR in a metrology chamber in accordance with another embodiment.

In FIG. 2C, a cluster tool 24 is a multi-chamber substrate processing apparatus capable of processing multiple substrates at one time. The cluster tool 24 comprises a plurality of processing chambers 282, with each processing chamber providing each processing for a substrate. The plurality of processing chambers 282 shares a transportation apparatus 284 and a plurality of loading ports 286. The transportation apparatus 284 moves substrates between different stations of the cluster tool 24, such as the process chambers 282 and loading ports 286. The cluster tool 24 further comprises a FTIR metrology chamber 288 that contains the in-situ double-transmission FTIR system. In such a configuration, for example, FTIR measurements may be performed between process steps and during a transport between different stations of the cluster tool 24. A controller 290 coupled (shown as a dot-dashed line) to various components of the cluster tool 24 (such as the processing chambers 282, the FTIR metrology chamber 288, and so on) or sensors (e.g., sensors located in or on the processing chambers 282, the transportation apparatus 284, and so forth) is capable of measuring an operating variable, such as a presence or profile of by-product residue.

In FIGS. 3A-3E, cross-sectional views of example substrates with patterns that may be characterized by the double-transmission FTIR are schematically illustrated in accordance with various embodiments.

In FIG. 3A, the substrate 100 may be a silicon wafer and in one embodiment, have a thickness between 100-2000 μm. The substrate comprises the back-side reflecting coating 102 on the back side of the substrate 100, and a thin film 103 over the front surface of the substrate 100. In one embodiment, the thin film 103 may be a silicon oxide formed by thermal oxidation and have a thickness between 0.1 nm and 500 nm. Because of the presence of additional interfaces (e.g., thin film 103-substrate 100 interface), additional reflection and refraction of the IR beam (e.g., the IR beam 112 in FIGS. 1A and 1B) may occur.

FIG. 3E illustrates an example diagram of light path near and within the substrate 100 illustrated in FIG. 3A. Similar to the embodiment described above referring to FIG. 1B, the IR beam 112 is directed to the substrate 100 at an incident angle of Brewster's angle 113, which may be at or near a Brewster's angle determined by the two media (air or vacuum and the substrate 100 as the bulk material) in the system. The IR beam 112 first impinges on the front surface of the thin film 103. The IR beam 112 may be split into two (a front-reflected IR beam 116B and the refracted IR beam). The first refracted IR beam has a first refraction angle 312. The first refracted IR beam is transmitted through the thin film 103 and next impinges on the front surface of the substrate 100. At this thin film 103-substrate 100 interface (an intermediate interface), a second reflection and a second refraction may occur. Accordingly, an intermediate-reflected IR beam 116C (reflected at the thin film 103-substrate 100 interface) may exit the thin film 103 and collected as a part of the reflected IR beam 117 that is directed to the IR detector (e.g., the optical sensor system 170 in FIG. 1A). At the second refraction, a second incident angle equals to the first refraction angle 312, and a second refraction angle 314 is determined by the Snell's law. The second refracted IR beam may be reflected at the back surface of the substrate 100 and be the back-reflected IR beam 116A. As a result, the reflected IR beam 117 may comprise three components: the back-reflected IR beam 116A, the front-reflected IR beam 116B, and the intermediate-reflected IR beam 116C.

Despite these additional reflections and refractions, the back-reflected IR beam 116A is transmitted both to the bulk of the substrate 100 and the thin film 103 at least twice before reaching to the IR detector (e.g., the optical sensor system 170 in FIG. 1A). Similarly, the intermediate-reflected IR beam 116C is transmitted the thin film 103 at least twice. Accordingly, the double-transmission FTIR measurements may offer high sensitivity for the thin film 103 as well as the substrate 100 over other conventional techniques.

In some embodiments, where the thin film 103 is thin enough, for example, less than half the thickness of the substrate 100, or for example, less than 5000 nm, the intermediate-reflected IR beam 116C may be ignored because the first refraction at the front surface of the thin film 103 may be negligible.

In other embodiments, where the thin film 103 is substantially thick relative to the substrate 100, for example thicker than a half of the substrate 100, the Brewster's angle may be determined by air or vacuum and the material of the thin film 103, instead of the substrate 100 as the bulk material. The incident angle of Brewster's angle may be selected to ensure and improve double-transmission of the IR beam 112 within the thin film 103.

In one embodiment, the first medium may be vacuum (n₁=1), the second medium (e.g., the thin film 103 in FIGS. 3A and 3E) may be a silicon oxide having a refractive index of about 1.5 (n₂=1.5), and the third medium (e.g., the substrate 100 in FIGS. 3A and 3E) may be a silicon having a refractive index of about 3.4 (n₃=3.4). The incident angle of Brewster's angle 113 may be 73.6°, where the first refraction angle 312 and the second refraction angle 314 are determined as 41.1° and 14.0°, respectively. This analysis is described for example only. It should be noted that a refractive index is a wavelength-dependent property, and the Brewster's angle needs to be determined or estimated based on refractive indexes in the corresponding IR region used in the FTIR measurements. In various embodiments, the Brewster's angle is calculated as an arctangent of a ratio of the refractive indexes of a first medium (e.g., air or vacuum) and one of a second (e.g., the thin film 103 in FIGS. 3A and 3E) or third medium (e.g., the substrate 100 in FIGS. 3A and 3E) which are determined for the wavelength range applied in FTIR measurements.

In FIG. 3B, the substrate 100 having vertical recesses comprises the back-side reflecting coating 102 on the back side of the substrate 100, and a filling material 105 over the vertical recesses in the substrate 100. In one embodiment, the substrate 100 may be a silicon wafer and the filling material 105 may comprise carbon such as amorphous carbon. Similarly to the previous example illustrated in FIG. 3A, the filling material 105 is also in the light path of the double-transmitted IR beam. Therefore, in addition to the substrate 100, the characteristics of the filling material 105 may also be qualitatively and/or quantitatively analyzed by the double-transmission FTIR measurements.

In FIG. 3C, the substrate 100 may be a silicon wafer having the back-side reflective coating 102 on the back side of the substrate 100, and the thin film 103 over the front surface of the substrate 100, where the thin film 103 has a vertical recess 106. The vertical recess 106 may be left as a void or be filled with another material. In this example, there are sidewalls in the thin film 103, and these sidewalls may also be subject to a deposition or etch process which may need to be monitored. If an FTIR measurement is performed in a reflection mode, a majority of the detectable IR beam comes from the front surface of the thin film 103 and may not contain information of sidewall surfaces. In contrast, the double-transmission FTIR is mainly based on the back-reflected IR beam (e.g., the back-reflected IR beam 116A), which may also be transmitted through the sidewalls. For example, a sidewall passivation layer formed may be detected and quantified by the double-transmission FTIR. Accordingly, with the embodiment system, it may be possible to characterize the deposition or etch process in terms of conformality or anisotropy.

In FIG. 3D, the substrate 100 may be a silicon wafer having the back-side reflective coating 102 on the back side of the substrate 100, and a layer stack with a vertical recess 106. The layer stack comprises a top and a bottom thin film 103 layers sandwiching an intermediate layer 107, where the vertical recess 106 extends to the bottom thin film 103. In some embodiments, the intermediate layer may comprise silicon, a metal, an oxide, a nitride, an oxynitride, a polymer, or other materials useful in device fabrication. The vertical recess 106 may be left as a void or filled with another material. Further, the substrate 100 comprises fins 108 with sidewalls covered with films 109. In some embodiments, the fins 108 may comprise silicon, a metal, an oxide, a nitride, an oxynitride, a polymer, or other materials useful in device fabrication, and the films 109 may comprise silicon, a metal, an oxide, a nitride, an oxynitride, a polymer, or other materials useful in device fabrication. In the same way as described in FIGS. 3A-3C, the IR beam may be transmitted through the layers, films, and materials illustrated in FIG. 3D, enabling FTIR analysis for various structures comprising sidewalls, horizontal surfaces, or layer boundaries in a patterned wafer. As would be understood by one of ordinary skill in the art, however, materials that do not absorb significant infrared light (IR) cannot be characterized or monitored by any FTIR method including double-transmission FTIR in this disclosure. For example, many metals reflect IR and some inorganic compounds such as KBr transmits most of the IR region.

In various embodiments, the substrate 100 may not have the back-side reflective coating 102. In certain embodiments, the back surface of the substrate 100 may be mirror polished, i.e., polished such that light reflects at the internal back surface.

Although various embodiments in this disclosure contemplate in-situ double-transmission FTIR measurements integrated with a semiconductor process, the system in this disclosure is not limited to in-situ measurement. In various embodiments, the double-transmission FTIR may be used ex-situ in characterizing different surface species on a substrate.

In one embodiment, Si—H bonds in silicon wafer may be identified by bands in the wavenumber range of 2000 cm⁻¹ to 2150 cm⁻¹, for example a band at around 2083 cm⁻¹.

In another embodiment, an organic polymer thin film, for example polystyrene thin film, may be identified.

Further, as described previously, the embodiment system may also detect IR beams reflected at or near the front surface of the substrate and IR beams transmitted more than twice within the bulk of the substrate, and is not strictly limited to detect only the double-transmitted IR beam (i.e., the back-reflected IR beam 116A in FIG. 1B).

In various embodiments, the double-transmission FTIR in this disclosure may be implemented in a semiconductor fabrication process as an in-situ diagnostic tool. The in-situ double-transmission FTIR measurements may offer benefits of reducing the need for conventional ex-situ characterization and thereby improving the process efficiency through faster optimization of process parameters. The embodiment system may also enable monitoring processed surface quality to correlate with process parameter and process performance. In addition, the embodiments may also improve the quality control with immediate detections of any faulty process, adding qualitative and/or quantitative values for process control.

FIG. 4 illustrates an example process flow of a cyclic layer-by-layer process comprising in-situ double-transmission FTIR measurements as a semiconductor process diagnostic tool in accordance with an embodiment. Examples of the cyclic layer-by-layer process include thermal and plasma atomic layer deposition (ALD) and atomic layer etch (ALE).

A cyclic layer-by-layer process 40 may comprise four main steps comprising two-self-limiting steps. First, a first gas comprising a first reactant is introduced to a processing chamber and the first reactant is adsorbed on the surface of a substrate to form a first layer (block 410). Second, the processing chamber is purged to remove any residual or excess first reactant (block 420). Next, a second gas comprising a second reactant is introduced to the processing chamber (block 430). In an example of atomic layer deposition (ALD), the second reactant is adsorbed over the first layer to form a second layer, or is reacted with the first layer to modify the first layer. In an example of atomic layer etch (ALE), the second reactant is reacted with the first layer and remove a layer of underlying materials. Fourth, the processing chamber is again purged to remove any residual or excess second reactant and any volatile products (block 440). Adsorption (deposition) and/or etch steps (e.g., blocks 410 and 430) may be performed using a plasma.

With the embodiment system in this disclosure, in-situ double-transmission MIR measurements may be performed during the cyclic layer-by-layer process described above at any stages as needed (e.g., blocks 410, 420, 430, or 440). It is possible to perform FTIR measurements simultaneously during a step or between steps. Unlike some other techniques, there may be no preparation needed for FTIR measurements such as tilting the substrate or attaching additional components (e.g., a special IR crystal or an external mirror).

In some embodiments, a high sensitivity allows the detection of less than a monolayer signal, such as only partial surface coverage with dangling bonds, during a cyclic process.

In one embodiment, in-situ double transmission FTIR measurements may be performed to monitor an atomic layer deposition (ALD) incubation time with a half-cycle sensitivity.

In an alternate embodiment, in-situ double-transmission FTIR measurements may be performed to monitor surface reactions at various steps of a thermal silicon oxide (e.g., SiO₂) ALE using hydrofluoric acid (HF) and trimethylaluminum (TMA). For example, a number of peaks between 900 cm⁻¹ and 1400 cm⁻¹ may be attributed to asymmetric Si—O stretching vibrations, and the progressive decrease of these peaks with ALE cycles may represent the layer-by-layer removal of silicon oxide. Further, in-situ double-transmission FTIR measurements may also quantitatively characterize dynamic changes of intermediate surface species such as Si—OH, Si—O, Si—CH₃, Si—F, Al—CH₃, Al—O, and Al—F. Such in-situ monitoring of various surface intermediate species may help understanding mechanisms of cyclic deposition or etch processes and enable precise process control and further process development.

Example embodiments of the invention are summarized here. Other embodiments can also be understood from the entirety of the specification as well as the claims filed herein. Reference numerals are added below for illustration purposes only and the various examples could be implemented differently and are not to be construed as being limited to only these illustrations.

Example 1. An apparatus includes a chamber (15, 288) that includes a first window and a second window; a substrate (100) holder configured to hold a substrate (100) in the processing chamber (15, 124); an infrared light (IR) source configured to generate a collimated IR beam (112); a first optical assembly (140) configured to transmit the collimated IR beam (112) into the chamber (15, 288) through the first transmissive window (123) and direct the collimated IR beam (112) at an incident angle of Brewster's angle with a front side of the substrate (100); and a second optical assembly (160) configured to receive the collimated IR beam (117) reflected at a back side of the substrate (100) through the second transmissive window (125) and direct the collimated IR beam (117) to an optical sensor system (170).

Example 2. The apparatus of example 1, where the IR source (110) and the first optical assembly (140) are integrated in a single component mounted on the first window and the second optical assembly (160) and the optical sensor system (170) are integrated in a single component mounted on the second window.

Example 3. The apparatus of one of examples 1 or 2, where the optical sensor system (170) includes an IR detector configured to output electrical signals representing a spectral content of the IR beam (117).

Example 4. The apparatus of one of examples 1 to 3, further including an optical lens/waveguide to further collimate and confine the collimated IR beam (112);

Example 5. The apparatus of one of examples 1 to 4, further including a beam polarizer (130) to polarize the IR beam (112) disposed in a path of the IR beam (112, 117) between the IR source (110) and the optical sensor system (170).

Example 6. The apparatus of one of examples 1 to 5, where the chamber (15) is a FTIR metrology chamber (288) in a cluster tool (24).

Example 7. The apparatus of one of examples 1 to 5, where the chamber (15) is a processing chamber further including a plasma source and a controller (290) configured to generate and sustain a plasma in the chamber (15).

Example 8. The apparatus of one of examples 1 to 7, where the incident angle of Brewster's angle is between 60° and 80°.

Example 9. The apparatus of one of examples 1 to 8, further including a scanner configured to move a position of the substrate (100) relative to the first optical assembly (140) and second optical assembly (160).

Example 10. An apparatus including: a chamber (15, 288); a substrate holder (104) configured to hold a substrate (100); an IR source (110) configured to generate an IR beam (112); a collimator (145) to collimate the IR beam (112) and generate a collimated IR beam (112); an IR detector (170) configured to output electrical signals representing a spectral content of the IR beam (117); a microprocessor (180); and a memory having a program including instructions to: direct the collimated IR beam (112) to a front side of the substrate (100) at an incident angle of Brewster's angle; direct the collimated IR beam (117) reflected from a reflective coating on a back side of the substrate (100) to the IR detector; detect and record an absorption of the reflected IR beam (117) at the IR detector; and obtain an IR absorption spectrum.

Example 11. The apparatus of example 10, the program further including an instruction to form the reflective coating on the back side of the substrate (100).

Example 12. The apparatus of one of examples 10 or 11, the program further including an instruction to change the incident angle of Brewster's angle.

Example 13. The apparatus of one of examples 10 to 12, where the substrate holder is configured to hold the substrate (100) separated from the substrate holder by a gap.

Example 14. An apparatus including: a processing chamber (15); a vacuum pumping system; a gas injection system; a substrate (100) holder configured to hold a substrate (100) in the processing chamber (15); an infrared light (IR) source configured to generate an IR beam (112, 117); a collimator (145) to collimate the IR beam (112) and generate a collimated IR beam (112); an IR detector configured to output electrical signals representing a spectral content of the IR beam (117); a microprocessor (180); and a memory having a program including instructions to: perform a process step in the processing chamber (15) to process the substrate (100); direct the collimated IR beam (112) to the substrate (100) at an incident angle of Brewster's angle; direct a reflected IR beam (117) from the substrate (100) to the IR detector; detect and record an absorption of the reflected IR beam (117) at the IR detector; and obtain a IR absorption spectrum of the substrate (100), where the IR source (110) is configured to generate an IR beam (117) and the IR detector is configured to detect the absorption during the process step.

Example 15. The apparatus of example 14, the program further including instructions to perform a diagnostic of the process step based on the IR absorption spectrum.

Example 16. The apparatus of one of examples 14 or 15, the program further including instructions to repeat the performing, directing the collimated IR beam (112), directing the reflected IR beam (117), detecting and recording the absorption, and obtaining the IR absorption spectrum.

Example 17. The apparatus of one of examples 14 to 16, where the process step is a part of an atomic layer deposition (ALD) or an atomic layer etch (ALE).

Example 18. The apparatus of one of examples 14 to 17, where the process step is a part of the ALD, and the program further including instructions to perform a diagnostic of the process step by monitoring a layer formed during the ALD based on the IR absorption spectrum.

Example 19. The apparatus of one of examples 14 to 18, where the process step is a part of the ALE, and the program further including instructions to perform a diagnostic of the process step by monitoring a layer removed by the ALE based on the IR absorption spectrum.

Example 20. The apparatus of one of examples 14 to 19, where the process step includes a plasma process step.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. An apparatus comprising:
a chamber comprising a first window and a second window;
a substrate holder configured to hold a substrate in the processing chamber;
an infrared light (IR) source configured to generate a collimated IR beam;
a first optical assembly configured to transmit the collimated IR beam into the chamber through the first window and direct the collimated IR beam at an incident angle of Brewster's angle with a front side of the substrate; and
a second optical assembly configured to receive the collimated IR beam reflected at a back side of the substrate through the second window and direct the collimated IR beam to an optical sensor system.

2. The apparatus of claim 1, wherein the IR source and the first optical assembly are integrated in a single component mounted on the first window and the second optical assembly and the optical sensor system are integrated in a single component mounted on the second window.

3. The apparatus of claim 1, wherein the optical sensor system comprises an IR detector configured to output electrical signals representing a spectral content of the IR beam.

4. The apparatus of claim 1, further comprising an optical lens/waveguide to further collimate and confine the collimated IR beam.

5. The apparatus of claim 1, further comprising a beam polarizer to polarize the IR beam disposed in a path of the IR beam between the IR source and the optical sensor system.

6. The apparatus of claim 1, wherein the chamber is a metrology chamber in a cluster tool.

7. The apparatus of claim 1, wherein the chamber is a processing chamber further comprising a plasma source and a controller configured to generate and sustain a plasma in the chamber.

8. The apparatus of claim 1, wherein the incident angle of Brewster's angle is between 60° and 80°.

9. The apparatus of claim 1, further comprising a scanner configured to move a position of the substrate relative to the first optical assembly and second optical assembly.

10. An apparatus comprising:
a chamber;
a substrate holder configured to hold a substrate;
an infrared light (IR) source configured to generate an IR beam;
a collimator to collimate the IR beam and generate a collimated IR beam;
an IR detector configured to output electrical signals representing a spectral content of the IR beam;
a microprocessor; and
a memory having a program comprising instructions to:
direct the collimated IR beam to a front side of the substrate at an incident angle of Brewster's angle;
direct the collimated IR beam reflected from a reflective coating on a back side of the substrate to the IR detector;
detect and record an absorption of the reflected IR beam at the IR detector; and
obtain an IR absorption spectrum.

11. The apparatus of claim 10, the program further comprising an instruction to form the reflective coating on the back side of the substrate.

12. The apparatus of claim 10, the program further comprising an instruction to change the incident angle of Brewster's angle.

13. The apparatus of claim 10, wherein the substrate holder is configured to hold the substrate separated from the substrate holder by a gap.

14. An apparatus comprising:
a processing chamber;
a vacuum pumping system;
a gas injection system;
a substrate holder configured to hold a substrate in the processing chamber;
an infrared light (IR) source configured to generate an IR beam;
a collimator to collimate the IR beam and generate a collimated IR beam;
an IR detector configured to output electrical signals representing a spectral content of the IR beam;
a microprocessor; and
a memory having a program comprising instructions to:
perform a process step in the processing chamber to process the substrate;
direct the collimated IR beam to the substrate at an incident angle of Brewster's angle;
direct a reflected IR beam from the substrate to the IR detector;
detect and record an absorption of the reflected IR beam at the IR detector; and
obtain a IR absorption spectrum of the substrate, wherein the IR source is configured to generate an IR beam and the IR detector is configured to detect the absorption during the process step.

15. The apparatus of claim 14, the program further comprising instructions to perform a diagnostic of the process step based on the IR absorption spectrum.

16. The apparatus of claim 14, the program further comprising instructions to repeat the performing, directing the collimated IR beam, directing the reflected IR beam, detecting and recording the absorption, and obtaining the IR absorption spectrum.

17. The apparatus of claim 14, wherein the process step is a part of an atomic layer deposition (ALD) or an atomic layer etch (ALE).

18. The apparatus of claim 17, wherein the process step is a part of the ALD, and the program further comprising instructions to perform a diagnostic of the process step by monitoring a layer formed during the ALD based on the IR absorption spectrum.

19. The apparatus of claim 17, wherein the process step is a part of the ALE, and the program further comprising instructions to perform a diagnostic of the process step by monitoring a layer removed by the ALE based on the IR absorption spectrum.

20. The apparatus of claim 14, wherein the process step comprises a plasma process step.
